(19) United States
(12) Patent Application Publication
(10) Pub. No.: US 2018/0252780 A1
(43) Pub. Date: Sep. 6, 2018

(54) MAGNETIC SENSOR

(71) Applicant: KABUSHIKI KAISHA TOSHIBA, Tokyo (JP)

(72) Inventors: Hitoshi IWASAKI, Tokyo (JP); Akira KIKITSU, Yokohama (JP); Satoshi SHIROTORI, Yokohama (JP); Masayuki TAKAGISHI, Tokyo (JP)

(73) Assignee: KABUSHIKI KAISHA TOSHIBA, Tokyo (JP)

(21) Appl. No.: 15/693,272

(22) Filed: Aug. 31, 2017

(30) Foreign Application Priority Data
Mar. 3, 2017 (JP) 2017-039967

(51) Int. Cl. G01R 33/09

(52) U.S. Cl. CPC G01R 33/091

(57) ABSTRACT

In one embodiment, a magnetic sensor has first and second electrode, a magneto-resistive effect element, an insulating layer between the first electrode and the element, a current source portion and a detecting portion. The element has a length in a first direction along a film surface of the element which is larger than that in a second direction along the film surface and perpendicular to the first direction. The element includes first, non-magnetic and second magnetic layers. The magnetization direction of the first magnetic layer is along the first direction. The element is connected to the first and second electrodes. The current source portion is connected to the first and second electrodes. The detecting portion can detect a second harmonic component in an output signal of the element. The first electrode and the element overlap each other in a third direction perpendicular to the first and the second directions.

### CROSS-REFERENCE TO RELATED APPLICATION

The application is based upon and claims the benefit of priority from the prior Japanese Patent Application No. 2017-039967, filed on Mar. 3, 2017,the entire contents of winch are incorporated herein by reference.

### FIELD

Embodiments described herein relate generally to a magnetic sensor.

### BACKGROUND

A magnetic sensor in which a magneto-resistive effect element is provided is proposed. The magnetic sensor is desired to have higher detection sensitivity.

### BRIEF DESCRIPTION OF THE DRAWINGS

FIG. 1 is a top view showing a main body of a magnetic sensor according to an embodiment.

FIG. 2 is a sectional view taken along line a1-a2 in FIG. 1.

FIG. 3 is a sectional view showing a main portion of FIG. 2.

FIG. 4A is an enlarged sectional view stowing a portion of a magneto-resistive effect element which is used in the magnetic sensor.

FIG. 4B is a sectional view showing a portion of another magneto-resistive effect element which can be used hi the magnetic sensor.

FIG. 5A is a top view showing a configuration of a portion of a main body of a magnetic sensor according to another embodiment.

FIG. 5B is a sectional view taken along line a1-a2 in FIG. 5A.

FIG. 5C is a sectional view taken along line c1-c2 in FIG. 5A.

FIG. 6 is a view illustrating a relationship between a current magnetic field H and a resistance R in the magnetic sensor.

FIGS. 7A and 7B are views respectively illustrating a relationship between a cycle of as alternating current and a voltage corresponding to the resistance R in the magnetic sensor according to the first embodiment.

FIGS. 8A and 8B are views respectively illustrating a second harmonic signal produced in proportion to positive and negative signal magnetic fields of the magnetic sensor.

FIGS. 9A and 9B are circuit block diagrams of detecting units which detect the second harmonic signal in the magnetic sensor, respectively.

FIG. 10 is a top view showing a main body of a magnetic sensor according to further another embodiment.

FIGS. 11 and 12 are views respectively showing simulation prediction of dependence of characteristics of the magneto-resistive effect element of the magnetic sensor shown in FIGS. 1 to 4A on the number of junction portions formed of a magnetic layer and a non-magnetic layer.

### DETAILED DESCRIPTION

According to one embodiment, a magnetic sensor has a first electrode, a second electrode, a magneto-resistive effect element, an insulating layer, a current source portion and a detecting portion. The second electrode is provided apart from the first electrode. The magneto-resistive effect element has a length in a first direction along a film surface of the magneto-resistive effect element which is larger than a length in a second direction along the film surface and perpendicular to the first direction. The magneto-resistive effect element includes a first magnetic layer, a non-magnetic layer and a second magnetic layer. The magnetization direction of the first magnetic layer is along the first direction. The magneto-resistive effect element is connected electrically to the first electrode and the second electrode. The insulating layer is provided between the first electrode and the magneto-resistive effect element. The current source portion is connected to the first electrode and the second electrode and can supply an alternating current to the magneto-resistive effect element. The detecting portion can detect a second harmonic component in an output signal of the magneto-resistive effect element. The first electrode and the magneto-resistive effect element overlap each other in a third direction perpendicular to the first and the second directions so as to extend along each other.

Hereinafter, further embodiments will be described with reference to the drawings.

In the drawings, the same reference numerals denote the same or similar portions respectively.

The drawings are schematic or conceptual, and a relation between the thickness and the width of each portion, and a size ratio of portions are not necessarily the same as an actual relation and size ratio. Even for the same portions, a different dimension and ratio may be illustrated depending on the drawings. In graphs, normalized values are shown in a case that any unit of horizontal or vertical axis is not mentioned.

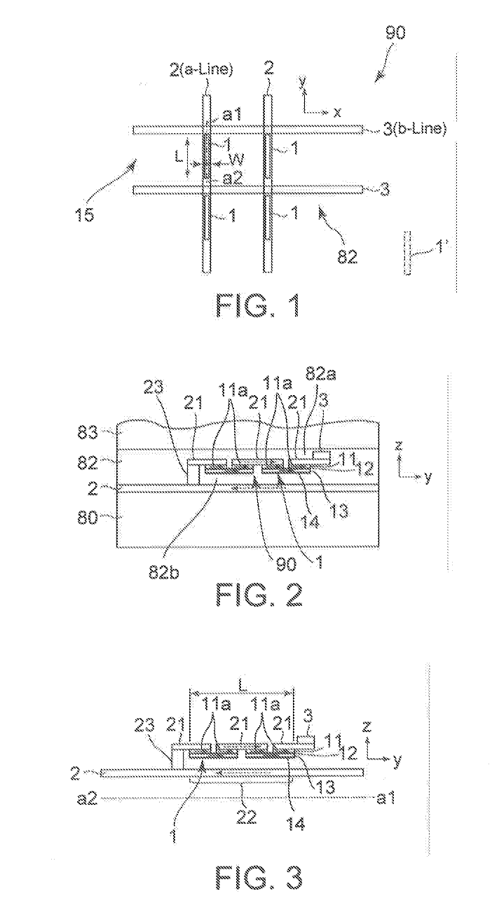

Embodiments will be described with reference to FIG. 1 to FIG. 4B.

FIG. 1 is a top view of a main body 90 of a magnetic sensor concerning an embodiment seen from above an insulating film which covers a plurality of magneto-resistive effect elements constituting the main body 90. FIG. 2 is a sectional view taken along line a1-a2 shown in FIG. 1. FIG. 3 is a sectional view showing a main portion of FIG. 2.

As shown in FIG. 2, a plurality of magneto-resistive effect elements 1 are arranged above an insulating substrate 80. The magneto-resistive effect elements 1 are arranged in parallel with one another, densely with a distance among one another, and substantially in a shape of lattice, on an X-Y plane 15.

As shown in FIG. 2, an insulating film 82 is formed so as to cover the substrate 80 and the magneto-resistive effect elements. The substrate 80 forms a magnetic sensor device in combination with the main body 90 of the magnetic sensor. The substrate 80 may be a flexible substrate which is used for a magnetoencephalograph or an electrocardiograph.

The magnetic sensor can measure a signal magnetic field of a sample 83 which is mounted on the insulating film 82.

For example, the magnetic sensor can measure a signal magnetic field (a magnetic field produced by cell activity) which is generated from a cell as a sample 83 cultured on the insulating film 82. It is possible to measure a signal magnetic field at high resolution by thinning the thickness of an insulating layer 82a which composes the insulating film 82 and is provided between the main body 90 of the magnetic sensor and the sample 83.

It is desirable for obtaining favorable resolution in detection of a magnetic field produced by cell activity that the thickness of the insulating film 82a between the main body 90 of the magnetic sensor and the sample 83 is set to about 1-20 μm.

Each magneto-resistive effect element 1 is formed in a rectangle which is long in a Y-direction as a first direction extending along a film surface i.e. a main surface and short in a X-direction as a second direction extending along the film surface and perpendicular to the Y-direction. For example, the length of each magneto-resistive effect element 1 in the Y-direction may be made 10 or more times larger than the length in the X-direction. When the length of each magneto-resistive effect element 1 in a longitudinal direction i.e. the Y-direction is “L”, the length L is 10-20 μm desirably. When activity from a group of cells id detected, a magneto-resistive effect element which has a length larger than the length L may be used.

The X-direction is a width direction of each magneto-resistive effect element 1, and each magneto-resistive effect element 1 has a width W. A Z-direction which is a third direction shows a direction perpendicular to the film surface of each magneto-resistive effect element 1.

Above the substrate 80, a plurality of wiring portions 2 (a-line) as first electrodes and a plurality of wiring portion 3 (b-line) as second electrodes which is shown in FIG. 1 intersect each other and arranged apart from each other in the Z-direction of FIG. 2. The wiring portions 2 are arranged in parallel with and apart from one another. The wiring portions 3 are arranged in parallel with and apart from one another.

The magneto-resistive effect elements are arranged respectively corresponding to intersecting portions of the wiring portions 2 and the wiring portions 3. Current flows in the magneto-resistive effect element 1 corresponding to each intersecting portion by flowing a current from one of the wiring portions 2 corresponding to each intersecting portion from one of the wiring portions 3 of a plurality of corresponding to each intersecting portion. When current flows in each magneto-resistive effect element 1, an output voltage is obtained according to a resistance value of the magneto-resistive effect element 1, and an external signal magnetic field is detected.

In the embodiment, a second harmonic signal which occurs in each magneto-resistive effect element 1 is detected as an output by flowing an alternating current from the wiring portions 2, 3 to each magneto-resistive effect element 1, as described below.

As shown in FIG. 3, an area 22 of a part of each wiring portion 2 as a first electrode which is provided above the substrate 80 is arranged closely to each magneto-resistive effect element 1 so that the area 22 covers an undersurface of the magneto-resistive effect element 1 from below in directly below the magneto-resistive effect element 1. The area 22 of the wiring portion 2 and the magneto-resistive effect element 1 overlap each other in the Z-direction. An insulating layer 82b which constitutes the insulating film 82 is provided between the wiring portion 2 and the magneto-resistive effect element 1.

As shown in FIGS. 2, 3, each magneto-resistive effect element 1 has a magnetic layer 11 as a free magnetic layer, a non-magnetic layer 12 as a middle layer, a magnetic layer 13 as a pin magnetic layer and a conductive underlayer 14. These layers are laminated in this order. In FIGS. 2, 3, the magnetic layer 11 is divided into a plurality of portions 11a across an insulation part of the insulating film 82 as described below. The non-magnetic layer 12. the magnetic layer 13, and the underlayer 14 are also divided into a plurality of portions, respectively. The divided portions are arranged apart from one another in the Y direction. The composition and material quality of these layers 12 to 14 will be described in detail below.

A plurality of electrodes 21 of a rectangle is provided on the portions 11a of the magnetic layer 11 of each magneto-resistive effect element 1. The portions 11a are electrically connected to the electrodes 21 respectively.

The portion 11a of the magnetic layer 11 of each magneto-resistive effect element 1 which is positioned, at a right side is electrically connected, with a wiring portion 3 as the second electrode via the electrode 21 positioned, at the right side. The portion 11a of the magnetic layer 11 at a left side is electrically connected with a wiring portion 2 as the first electrode via an electrode 21 positioned at the left side and an electrode 23 as a fourth electrode. The portion 11a at middle are electrically connected to the electrode 21 at middle. Current flows in the wiring portion 2 and the electrodes 21 as indicated by an arrow of a dashed line by supplying electric power between the wiring portions 2, 3. A current flow meandering up and down in the Z-direction is formed by the magnetic layer 11, the non-magnetic layer 12, the magnetic layer 13 and the underlayer 14 which are divided into plurality, respectively.

The surface of the insulating film 82 which covers the magneto-resistive effect elements 1 has less unevenness desirably.

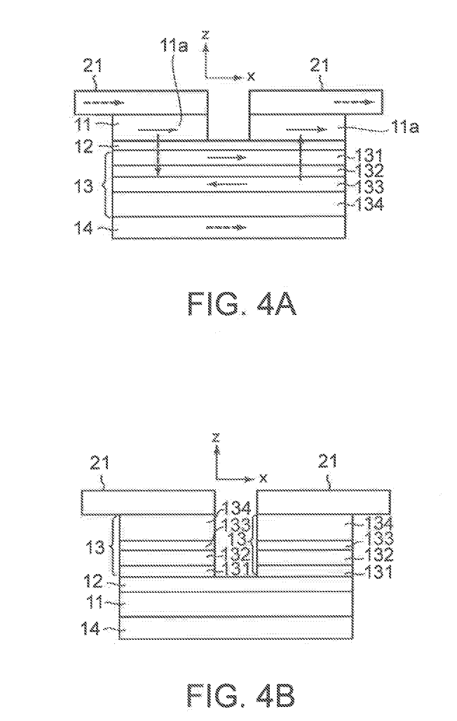

FIG. 4A is an enlarged sectional view showing a right half of a magneto-resistive effect element 1 of the magnetic sensor shown in FIG. 2. A left half of the magneto-resistive effect element 1 has also the same structure. FIG. 4B is an enlarged sectional view shewing a right half of another example of a magneto-resistive effect element which can be used for the magnetic sensor. A left half of the other example of the magneto-resistive effect element has also the same structure.

In FIG. 4A, the magnetic layer 11 which is a free magnetic layer is arranged as an upper layer of the magneto-resistive effect element 1, and the magnetic layer 18 which is a pin magnetic layer is arranged as a lower layer of the magneto-resistive effect element 1. The non-magnetic layer 12 is provided as a middle layer between the magnetic layers 11 and 13. The underlayer 14 is provided so as to contact an undersurface of the magnetic layer 13.

The magnetic layer 11 is divided into the portions 11a, and the portions 11a are arranged so that the portions 11a are provided apart from, one another along a X-direction. This X-direction shown in FIG. 4A corresponds to the Y-direction shown in FIGS. 1 to 3. The electrodes 21 which are electrically connected to the wiring portions 2 and 3 as the first and the second electrodes axe formed on the portions 11a of the divided magnetic layer 11.

A material such as CoFeB which is suitable for magneto-resistive effect is desirably used for an interface portion of the magnetic layer 11 as a free layer and the non-magnetic layer 12. A soil magnetic layer such as NiFe is desirably used for a portion of the magnetic layer 11 provided apart from the interface. A material which shows a large tunnel magneto-resistive effect such as MgO can be used for the non-magnetic layer 12. The magnetic layer 13 which is a pin magnetic layer is composed of magnetic layers 131 to 134. The magnetic layer 131 can be a layer such as CoFeB which is suitable for occurring of magneto-resistive effect. The magnetic layer 132 can be a Ru (Ruthenium) layer. A layer such as a CoFe layer can. foe the magnetic layer 133. The magnetic layer 134 can be an antiferromagnetism layer such as IrMn for establishing magnetization. The underlayer 14 has desirably a resistance as low as possible and. can be composed of Ta, Ru or Cu, because the underlayer 14 serves as a wiring portion in which current can be flowed. The underlayer 14 has a lower resistivity than the magnetic layers 11, 13.

With such a configuration, a current flows as shown by arrows of dashed lines in FIG. 4A so that a tunnel current flows in a direction perpendicular to a film surface of the magneto-resistive effect element 1 via the non-magnetic layer 12 which is an insulating layer.

The portion that is the right half of the magnetic layer 13 and is shown, in FIG. 4A is not divided. The magnetic layer 13 has a rectangular shape of a length equal to or more than twice the length of the magnetic layer 11 in the X-direction. The magnetic layer 13 is magnetized so that magnetization of the magnetic layer 13 which is a pin magnetic layer becomes a longitudinal direction i.e. the X-direction. The magnetization of the magnetic layer 11 which is a free magnetic layer is also magnetized to be the same longitudinal direction i.e. the X-direction by the interlayer magnetic coupling between the magnetic layer 11 and the magnetic layer 13. The width W of the magneto-resistive effect element 1 is set to 0.5-1 micrometer. The length L is set to 10 micrometers equal to or more. Thus, L/W>10, which enables use of shape magnetic anisotropy. It is desirable to form the magneto-resistive effect element 1 in such a shape in order to make magnetization, of the magnetic layers 11 and 13 face the longitudinal direction hi a state that no external magnetic field is present. When the magnetic layer 13 which is a pin layer is magnetized in a width direction, dispersion in the magnetization direction of magnetic layers 11 and 13 occurs so that magnetic noise becomes difficult to be reduced.

The structure shown in FIG. 4B can be used instead of the structure of magneto-resistive effect element 1 of FIG. 4A in the magnetic sensor. The structure of FIG. 4B has a structure which is obtained by reversing the positions of magnetic layer 13 and magnetic layer 11 set in the structure of FIG. 4A up and down. The magnetic layer 13 which is a pin magnetic layer is arranged as an upper layer of the magneto-resistive effect element. The magnetic layer 11 which is a free magnetic layer is arranged as a lower layer of the magneto-resistive effect element. The magnetic layer 13 is divided into a plurality of portions, and the divided portions are apart from each other in the Y-direction.

Another magneto-resistive effect element can be obtained by couple a plurality of the structure shown in FIG. 4A or FIG. 4B with one another in series via the electrodes 21, which as described below.

The distance between each magneto-resistive effect element 1 in the magnetic sensor of the embodiment mentioned above and the area 22 of each wiring portion 2 close to the magneto-resistive effect element 1 is set to 0.5-3 μm, for example. The distance may be adjusted according to the intensity of an alternating current magnetic field which is added to the magneto-resistive effect element 1. When the inclination of a resistance vs. magnetic field characteristic of the magneto-resistive effect element 1 relating to magnetic field to resistance is steep, a required magnetic field may be small. Accordingly, it is desirable to arrange the area 22 of each wiring portion 2 apart from each magneto-resistive effect element 1.

When the number of junction portions i.e. interface surfaces or junctions of the divided portions 11a of the magnetic layer 11 and the insulating layer that is the non-magnetic layer 12 is increased in each magneto-resistive effect element 1, the resistance of the junction portions needs to be small in order to realize a resistance of 1-10 kΩ which are considered to be proper for the whole magnetic sensor. When the resistance of the junction portions is made small, increase of tunnel current becomes possible so that magnetic field which is produced by alternating current increases. Thus, it is desirable to make the area 22 of the wiring portion 2 and the magneto-resistive effect element 1 apart from each otter using the insulating layer 82b.

FIG. 1 shows a case where a plurality of areas of the wiring portions 2 respectively close to the magneto-resistive effect elements 1 are provided according to the number of lines of the wiring portions 2. Such a configuration enables detecting a state of cells in a space between the areas by light.

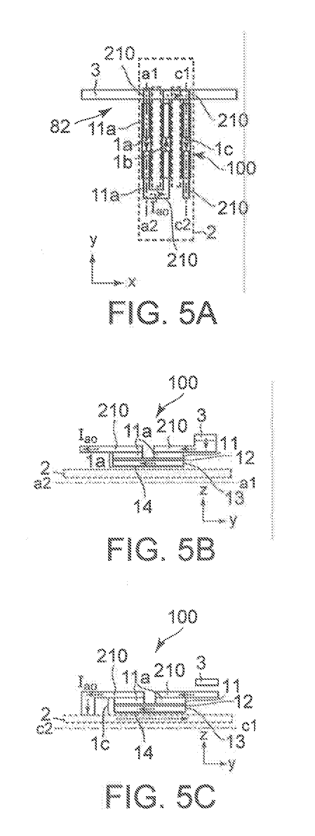

FIG. 5A to FIG. 5C show a part of a main portion of a magnetic sensor according to another embodiment. FIG. 5A is a top view. FIG. 5B is a sectional view taken along a line a1-a2 of FIG. 5A. FIG. 5C is a sectional view taken along a line c1-c2 line of FIG. 5A.

In a magneto-resistive effect element 100 of the embodiment, three structure portions 1a to 1c which have the same structure as that shown in FIG. 4A are arranged apart from one another so that a longitudinal direction of the structure portions 1a to 1c is the Y-direction. The structure portions 1a to 1c are connected in Series with four electrodes 210. Each of structure portions 1a to 1c has a magnetic layer 11 as a free magnetic layer, a magnetic layer 13 as a pin magnetic layers, a non-magnetic layer 12 sandwiched between the magnetic layers 11 and 13, and an underlayer 14 which contacts an undersurface of the magnetic layer 13. Each magnetic layer 11 of the structure portions 1a to 1c is divided into two portions 11a in the Y-direction. An end portion of the structure portion 1a which is the nearest to a1 in the longitudinal direction (the Y-direction) is connected to the wiring portion 3 via one of the electrodes 210. An end portion of the structure portion 1c which is the nearest to c2 in the longitudinal direction (the Y-direction) is connected, to the wiring portion 2 via another one of the electrodes 210. The two remaining electrodes 210 near a2 and c1 have a shape of an U-character, and are connected to ends of the structure portions 1a, 1b and ends of the structure portions 1b, 1c, respectively. The electrodes 210 connected to the wiring portions 2 and 3 are rectangles. The structure portions 1a to 1c of the magneto-resistive effect element 100 are connected in series with the electrodes 210 so that the number of junction portions i.e. interface surfaces or junctions of the divided portions 11a of the magnetic layer 11 and the insulating layer as the non-magnetic layer 12 can be increased. A current channel is formed as meandering up and down in the Y-direction and up and down in the Z-direction with the structure portions 1a to 1c and the electrodes 210.

When, the number of interface surfaces of the magnetic layer 11 and the non-magnetic layer 12 which is an insulating layer is increased, increase of output voltage may be attained. Increase of output voltage also increases 1/f noise. The 1/f noise indicates a noise signal having a frequency spectrum corresponding to an inverse of a frequency.

However, the magnetic sensor according to the embodiment mentioned above, employs a circuit which detects a second harmonic wave from an output voltage of the magneto-resistive effect element 1, as described below. Since alternating frequency increases even if output voltage increases when the circuit which detects the second harmonic wave is used, 1/f noise can be reduced. As a result, increase of output voltage and improvement of S/N ratio can be attained simultaneously.

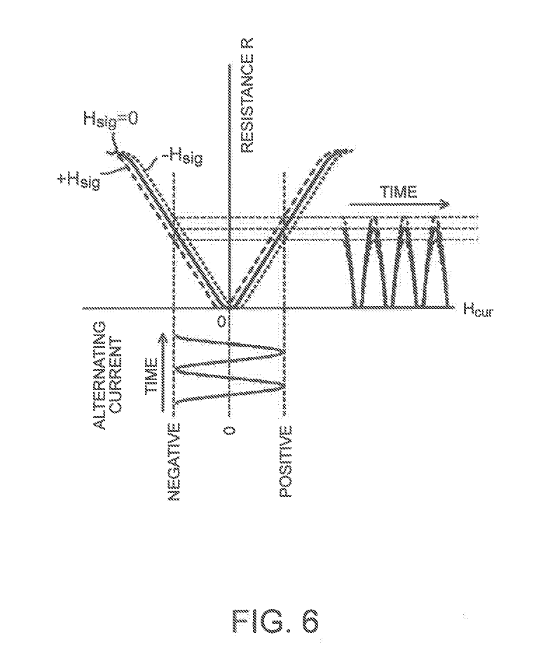

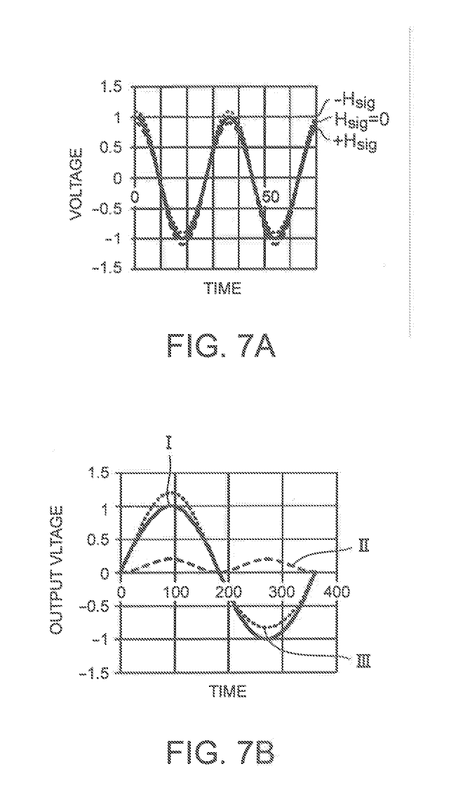

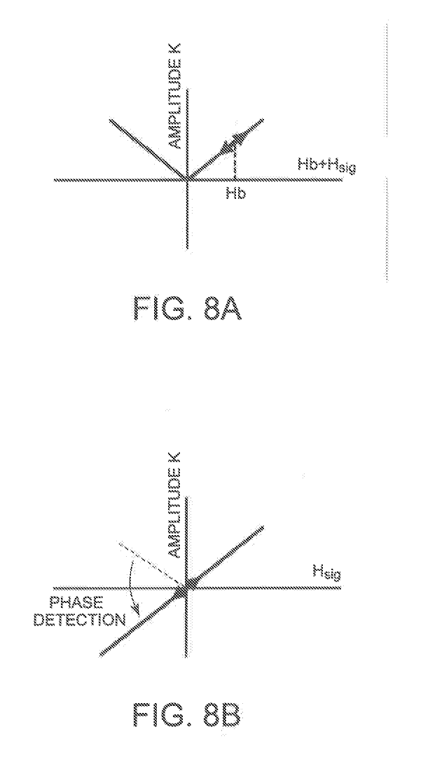

FIG. 6 is a view illustrating a relationship between a current magnetic field H which is produced by an alternating current and a resistance R of each magneto-resistive effect element 1 in the magnetic sensor 20.

More specifically, FIG. 6 illustrates a relationship between the current magnetic field H and the resistance R under presence of a positive signal magnetic field+H_{sig} from an outside of the magnetic sensor 20, a zero signal magnetic field, i.e., H_{sig}=0 and a negative signal magnetic field −H_{sig} from the outside.

The magneto-resistive effect element 1 uses a change in a resistance caused by a magnetic field component of each magneto-resistive effect element 11 in the width direction (the y-axis direction). Accordingly each signal magnetic field from the outside is applied to each magneto-resistive effect element hi the width direction (the y-axis direction) similar to the current magnetic held. Further, FIG. 6 illustrates a relationship between an alternating current cycle and a resistance fluctuation cycle too.

Resistance-increasing characteristics axe symmetrical with respect to positive and negative currents under presence of the zero signal magnetic field., i.e., H_{sig}=0, and respective magnetization rotation angles agree when absolute values of the positive and negative currents are the same. When the absolute values of the positive and negative currents are the same, the resistance fluctuations with respect to alternating currents denote the same value. When the positive signal magnetic field+H_{sig} is applied, the symmetrical resistance characteristics with respect to the positive and negative currents shift toward a negative current side. The magnetization rotation amount is large under presence of the positive current magnetic field, and the resistance R becomes large. The resistance R becomes low under presence of the negative current magnetic field. When the negative signal magnetic field −H_{sig} is applied to each magneto-resistive effect element 1 in the width direction (the y-axis direction), the symmetrical resistance characteristics with respect to the positive and negative currents shift toward a positive current side. The magnetization rotation amount becomes small under presence of the positive current magnetic field, and the resistance R becomes low. The resistance R becomes large under presence of the negative current magnetic field. As a result, when a signal magnetic field is applied from the outside, the resistance values with respect to the positive and negative current magnetic fields become different from each other. The difference is proportional to an intensity of the signal magnetic field in a range of linear magnetic field-resistance characteristics.

FIGS. 7A and 7B are views respectively illustrating relationships between a cycle of an alternating current and a voltage corresponding to the resistance R of each magneto-resistive effect element 1.

A voltage signal matching a current cycle is obtained under presence of the zero signal magnetic field, i.e., H_{sig}=0. When the positive signal magnetic field is applied, a voltage signal at the positive current side increases, and a signal voltage at the t current side decreases. In contrast, when the negative signal magnetic field is applied, the voltage signal at the negative current side decreases, and the voltage signal at the positive current side increases. In FIG. 7B, a graph I shews a case in which a signal magnetic field does not exist. When the signal magnetic field is applied, a waveform formed by combining a second harmonic signal having a frequency 2f which is twice a current frequency f is produced as shown by a graph II and a waveform formed by combining the second harmonic signal and the signal of the current frequency f is produced as shown by a graph III. The output voltage phases of the positive and negative fields differ from each other by 180 degrees. Accordingly it is possible to detect positive and negative signal magnetic fields by detecting a second harmonic signal produced in proportion to the positive and negative signal magnetic fields together with detecting the phase, if necessary. Alternatively, it is possible to detect the positive and negative signal magnetic fields by applying a bias magnetic field which is produced by a direct current in the same direction as the direction of the signal magnetic field without detecting the phase.

FIGS. 8A and 8B are views illustrating an amplitude K of a second harmonic signal produced in proportion to positive and negative signal magnetic fields of the magnetic sensor 20, respectively. The vertical axis shows the amplitude K of the second harmonic signal, and the horizontal axis shows intensity of the signal magnetic fields.

As illustrated in FIG. 8A, in a case where there is a positive bias magnetic field sufficiently larger than a signal, magnetic held, the second harmonic signal increases when the positive signal magnetic field is applied on the basis of a second harmonic signal produced by zero signal magnetic field. In the case, the second harmonic signal decreases when the negative signal magnetic field is applied.

It is possible to apply a bias magnetic field H_{b} by superimposing a direct current of a minute amount on the alternating current to magneto-resistive effect elements. The frequency of the alternating current is set to a value winch is one digit or more higher than a frequency of the signal magnetic field. For Application to a magnetoencephalography or an electrocardiograph, the frequency of the alternating current is 1 kHz or more desirably. The frequency of the alternating current is several tens of kHz desirably when, a nerve cell activity of approximately 1 kHz is detected. Superimposing the direct current can also realize a zero state of the second harmonic signal under presence of the zero signal magnetic field. In the case, as illustrated in FIG. 8B, it is possible to obtain, a voltage output by detecting the phase of the second harmonic signal and inverting the polarity of a negative second harmonic signal.

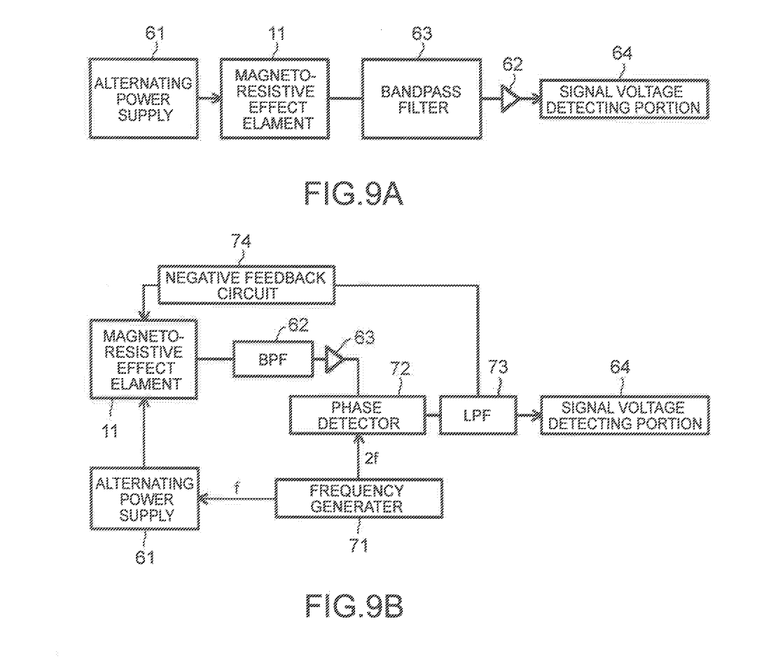

FIGS. 9A and 9B are a circuit block diagram of a detecting unit which detect a second harmonic signal in the magnetic sensor, respectively.

FIG. 9A illustrates an example of a circuit of one of the detecting units which uses the bias magnetic field to detect a second harmonic signal and which is used when a phase is not detected. An alternating current power supply 61 as a current source portion generates an alternating current including a direct current offset component for applying a bias magnetic field. The alternating current power supply 61 supplies the alternating current to the magneto-resistive effect elements 1. The frequency f of the alternating current is set to a value sufficiently larger than a maximum frequency of a detected magnetic field such as a value which is one digit higher, for example.

A bandpass filter 63 narrows a passband of a voltage output generated by each magneto-resistive effect element 1 to a proximity of the frequency 2f corresponding to the second harmonic signal. An amplifier 62 amplifies an amplitude voltage of the obtained second harmonic signal and a signal voltage detecting unit 64 detects the amplitude voltage as a signal voltage.

According to such a configuration, the band of the signal voltage is limited to the proximity of the frequency 2f so that an SN ratio becomes better The sensor can operate stably by adjusting the direct current offset component and controlling the intensity of the bias magnetic field. The detection of the second harmonic signal in the example can be regarded as detection of a difference between outputs of positive and negative current magnetic fields in the proximity of the frequency 2f. Consequently, it is possible to cancel or reduce an influence of amplitude fluctuation noise of a long-cycle such as 1/f.

FIG. 9B illustrates a circuit of the other one of the detecting units to detect a second harmonic signal. The value of the second harmonic signal which is output from the circuit is zero when an intensity of a signal magnetic field is zero. An alternating current of a frequency f is generated in an alternating current power supply 61 by using a signal of the frequency f from a frequency generator 71. Further, the alternating current power supply 61 adds a direct current offset component to the alternating current, and supplies the alternating current to which direct current offset component is added to each magneto-resistive effect element 1. A bandpass filter 63 has a passband. in the proximity of a frequency which is twice the frequency f, and causes a voltage signal to pass through the bandpass filter 63. The voltage signal corresponds to a change in a resistance of each magneto-resistive effect element 11. Then, an amplifier 62 amplifies the voltage signal. A signal voltage detecting unit 64 detects a second harmonic signal alter processing of the voltage signal in a phase detector 72 and a lowpass filter 73, which is described hi detail below. It is possible to generate a second harmonic signal of substantially zero when, a signal magnetic field is aero as illustrated in FIG. 5B, by adjusting the direct current offset component. The phase detector 72 refers to a signal of the frequency 2f obtained from the frequency generator 71, and extracts a second harmonic signal produced due to distortions at a positive side and a negative side. Further, the lowpass filter 73 cancels noise of the phase detector 72. The noise cancellation enables the signal voltage detecting unit 64 to receive the second harmonic signal with a higher SN ratio. A negative feedback circuit 74 feeds back a detection signal from the lowpass filter 73 to each magneto-resistive effect element 11 so that it is possible to obtain better linear responsiveness of the second harmonic signal corresponding to a signal magnetic field. As a result, it is possible to obtain a relationship of a linear response between the signal magnetic field and the second harmonic as illustrated in FIG. 5B. The negative feedback circuit 74 may be used to adjust the direct current offset component.

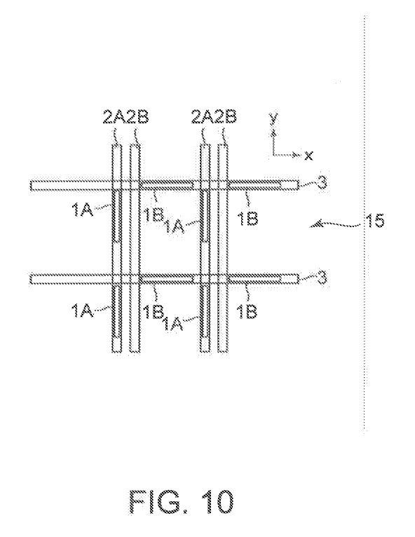

FIG. 10 is a top view showing a main portion of a magnetic sensor according to another embodiment.

In the embodiment, a plurality of wiring portions 2A as first electrodes and a plurality of wiring portions 2B as third electrodes are arranged close to each other with a distance between the wiring portions 2A, 2B and in parallel with each other in a Y-direction. A plurality of wiring portions 3 as second electrodes are arranged close to each other with a distance among the wiring portions 3 and in parallel with one another in a X-direction. The wiring portions 2A, 2B and the wiring portions 3 extend to intersect each other vertically. A plurality of magneto-resistive effect elements 1A which, are arranged in a shape of a lattice so that the longitudinal direction of the elements 1A is the Y-direction as the magneto-resistive effect elements 1 shown in FIG. 1 or FIG. 5A. A plurality of magneto-resistive effect elements 1B which are arranged in a shape of a lattice so that the longitudinal direction of the elements 1B is the X-direction. Any one of the wiring portions 2 and some of the magneto-resistive effect elements 1A which are provided along the same column overlap in the Z-direction. Any one of the wiring portions 3 and some of the magneto-resistive effect elements 1B which are provided along the same column overlap in the Z-direction. The wiring portions 2B are alternately arranged among the wiring portions 2A with a different distance between neighbored electrodes.

The wiring portions 3 are used commonly by the magneto-resistive effect elements 1A and the magneto-resistive effect elements 1B. Thus, some of the magneto-resistive effect elements 1A and some of the magneto-resistive effect elements 1B respectively corresponding to the same column are connected commonly to the same one of the wiring portions 3. The magneto-resistive effect elements 1A and the magneto-resistive effect elements 1B detect signal magnetic fields separately, and thus are connected respectively to the wiring portions 2A and the wiring portions 2B corresponding to the same column. The structures of the magneto-resistive effect elements 1A and 1B and the connections of the elements 1A and 1B with the wiring portions 2A and 2B may be the structures and the connections shown in FIGS. 2 and 3 or FIGS. 5B and 5C.

When a signal magnetic field is detected by one of the magneto-resistive effect elements 1A and one of the magneto-resistive effect element 1B corresponding to an arbitrary row and column, an X-direction component and a Y-direction component of the signal magnetic field can be measured. Accordingly, vector information on a signal magnetic field produced by a cell, for example, within the two dimensions of the X-Y plane 15 can be acquired.

A sensor group composed of the magneto-resistive effect elements 1A may be arranged in a first plane and another sensor group may be arranged in a second plane which is located above and in parallel to the first plane so that vector information on a signal magnetic field produced by a cell is acquired.

In the embodiments described above, large noise occurs in a voltage output of an alternating frequency wave i.e. a fundamental wave or a voltage output of an odd-ordered harmonic wave in a state where no signal magnetic field is present. Since such a noise is large compared with a second harmonic wave generated by a signal magnetic field, the noise is difficult to be completely removed by filtering using a circuit.

It is possible to remove a component unrelated to a signal magnetic field by using a White-stone-bridge which is generally used in a magnetic sensor, for example, but, in this case, four magneto-resistive effect elements are needed corresponding to each intersecting position of a row and column. Thus, it is difficult to increase integration and resolution of a magnetic sensor including magneto-resistive effect elements.

In order to remove noise of an alternating frequency wave i.e. a fundamental wave or an odd-ordered harmonic wave, reference magneto-resistive effect elements can be used. For example, in FIG. 1, a reference magneto-resistive effect element 1′ which has a shape and characteristics dose to those of each magneto-resistive effect element 1. for use in detecting magnetic field is provided at a place where signal magnetic field is decreased greatly. Noise can be removed, by using a differential output between a reference signal acquired from the reference magneto-resistive effect element 1′ and an output signal of the magneto-resistive effect element 1 for detecting magnetic field, as a detection signal.

In order to compensate the variation in the characteristics of the reference magneto-resistive effect element 1′ and the magneto-resistive effect element 1, a circuit winch feeds back a difference of the characteristics of the reference magneto-resistive effect element 1′ and the magneto-resistive effect element 1 and modifies an output signal can be used.

Further, in order to decrease signal magnetic field to be inputted into the reference magneto-resistive effect element 1′, the reference magneto-resistive effect element 1′ may be covered with a magnetic shield, or the reference magneto-resistive effect element 1′ may be arranged at a position sufficiently apart from a living body to be measured. The reference magneto-resistive effect element 1′ may be also incorporated in a signal-processing circuit which processes an output signal of the magneto-resistive effect element 1.

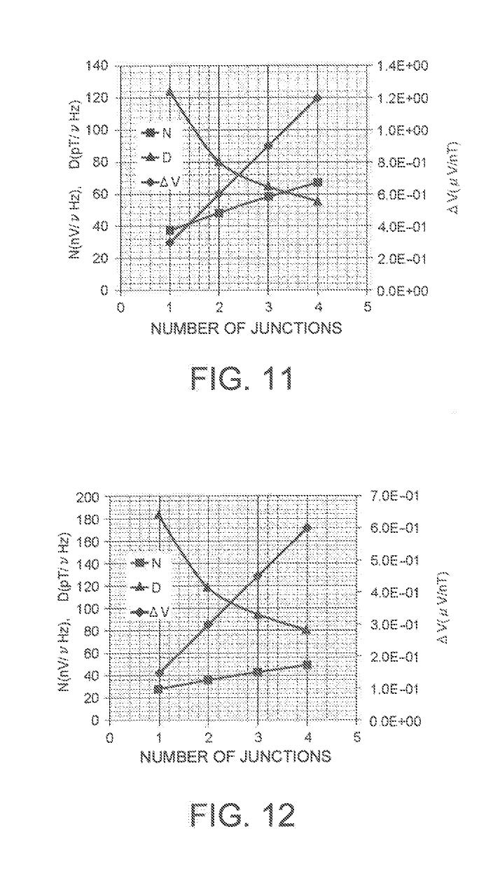

FIG. 11 shows simulation predictions of dependence of characteristics of a magneto-resistive effect element of a magnetic sensor as shown in FIGS. 1 to 4A on the number of junction portions which are formed of divided portions of a free magnetic layer and an insulating layer as a non-magnetic layer, i.e. the number of interface surfaces or the number of junctions.

Specifically, FIG. 11 shows simulation predictions of a reproduction output ΔV, a noise N composed of a 1/f noise and a Johnson thermal noise and a detection sensitivity D for a minimum magnetic field under which a signal output equals to a noise, as characteristics of the magneto-resistive effect element, respectively.

FIG. 11 shows the simulation predictions when the length L in the longitudinal direction of the magneto-resistive effect element is set to 20 μm.

The mutual, gap among a plurality of divided portions of a magnetic layer i.e. a free magnetic layer is set to 1 μm. The length W of the magneto-resistive effect element in a width direction is set to 1 μm, the resistance change rate of the magneto-resistive effect element is set to 150%, and the voltage which is applied to junction portions is set to 0.5V.

Further, the Hooge constant α of the 1/f noise is set to 5×10^{-8 μ}m², the alternating frequency of an alternating power supply is set to 10 MHz. the saturation magnetic field of the magneto-resistive effect element in a width direction is set to 50 O e. The area resistance product of the junction portions is adjusted so that the electrical resistance of the magnetic sensor is 1 kΩ μm².

The voltage of the whole magnetic sensor increases in proportion to the series number of the junction portions.

FIG. 12 shows the ease where length L of a magneto-resistive effect element of a magnetic sensor as shown in FIGS. 1 to 4A is set to 10 μm in a longitudinal direction.

Specifically, FIG. 12 shows simulation predictions of dependence of characteristics of a magneto-resistive effect element of the magnetic sensor shown in FIGS. 1 to 4A on the number of junction portions which are formed of divided portions of a free magnetic layer and an insulating layer as a non-magnetic layer, i.e. the number of interface surfaces or the number of junctions.

Similarly to the case of FIG. 11, according to the case of FIG. 11, the mutual gap among a plurality of divided portions of a magnetic layer i.e. a free magnetic layer is set to 1 μm, the length W of the magneto-resistive effect element in a width direction is set to 1 μm, the resistance change rate of the magneto-resistive effect element is set to 150%, and the voltage which is applied to junction portions is set to 0.5V. Further, the Hooge constant α of the 1/f to 5×10−8 μm², the alternating frequency of an alternating power supply is set to 10 MHz, the saturation magnetic field of the magneto-resistive effect element in a width direction, is set to 50 O e. The area resistance product of the j unction portions is adjusted so that the electrical resistance of the magnetic sensor is 1 kΩ μm².

Under the above simulation conditions, the predicted amount of signal magnetic field produced by a cell is several nT (nano tesla) according to a magnetic sensor including a magneto-resistive effect element of a thin shape having a length L of 10-20 μm.

However, the detection sensitivity D for a minimum magnetic field is predicted as D<0.2 nT (=200 pT (pico tesla)), and a detecting output which is larger than a noise by about one digit may be expected. When the number of magneto-resistive effect elements is increased, the detection sensitivity D for a minimum magnetic field further fells and the signal, detection can indicates a favorable S/N ratio.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Further, a form which is obtained by combining any two or more elements shown in each embodiment or example within a technically possible range would also fall within the scope and spirit of the inventions and be included in the inventions mentioned in the accompanying claims and their equivalents.

The magnetic sensor devices using the magnetic sensors according to the above embodiments would also belong to a range of the inventions.

What is claimed is:

1. a first electrode;
a second electrode which is provided apart from the first electrode;
a magneto-resistive effect element having a length in a first direction along a film surface of the magneto-resistive effect element which is larger than a length in a second direction along the film surface and perpendicular to the first direction, the magneto-resistive effect element including a first magnetic layer, a non-magnetic layer and a second magnetic layer, the magnetization direction of the first magnetic layer being along the first direction, further the magneto-resistive effect element being connected electrically to the first electrode and the second electrode;
an insulating layer provided between the first electrode and the magneto-resistive effect element;
a current source-portion which is connected to the first electrode and the second electrode and for supplying an alternating current to the magneto-resistive effect element;
a detecting portion which can detect a second harmonic component in an output signal of the magneto -resistive effect element, wherein
the first electrode and the magneto-resistive effect element overlap each other in a third direction perpendicular to the first and the second directions so as to extend along each other.

2. The magnetic sensor according to claim 1, wherein the first electrode and the second electrode are arranged to intersect each other.

3. The magnetic sensor according to claim 1, wherein the non-magnetic layer contains MgO.

4. The magnetic sensor according to claim 1, wherein the length the magneto-resistive effect element in the first direction is 10 or more times larger than that in the second direction.

5. The magnetic sensor according to claim 1, further comprising a bandpass filter, wherein the bandpass filter receives an output signal from the magneto-resistive effect element and restricts the output signal to a signal component in the vicinity of a frequency twice the frequency of the alternating current to output to the detecting portion.

6. The magnetic sensor according to claim 1, wherein the current source portion can further supply a direct current which has a current value smaller than that of the alternating current.

7. The magnetic sensor according to claim 1, further comprising a reference magneto-resistive effect element, wherein a difference between an output which is obtained by flowing current in the reference magneto-resistive effect element and another output which is obtained by flowing current in the magneto-resistive effect element which overlaps the first electrode is detected.

8. The magnetic sensor according to claim 1, further comprising a third electrode and another magneto-resistive effect element which has a length in the second direction larger than a length in the first direction, wherein
the second electrode and the other magneto-resistive effect element overlap each other in a third direction so as to extend along each other, and a current is flowed in the other magneto-resistive effect element with the third electrode and the second electrode.

9. The magnetic sensor according to claim 8, wherein the first electrode and the second electrode are arranged to intersect each other, and the third electrode and the second electrode are arranged to intersect each other.

10. The magnetic sensor according to claim 8, wherein the magnetic sensor includes a plurality of first electrodes, a plurality of second electrodes arranged to intersect the first electrodes, a plurality of magneto-resistive effect elements overlapping the first electrode and a plurality of other magneto-resistive effect elements overlapping the second electrode, and the magneto-resistive effect elements overlapping the first electrodes are arranged along the first electrodes and the other magneto-resistive effect elements overlapping the second electrodes are arranged along the second electrodes so that the magneto-resistive effect elements and the other magneto-resistive effect elements are disposed in a shape of lattice.

11. The magnetic sensor according to claim 1, further comprising another insulating layer provided on the magneto-resistive effect element, wherein a cell of a living body can be arranged on the other insulating layer.

12. The magnetic sensor according to claim 2, wherein the first electrode extends in the first direction, and the second electrode extends in the second direction.

13. The magnetic sensor according to claim 10 wherein the first electrode and the third electrode extend in the first direction, and the second electrode extends in the second direction.

14. The magnetic sensor according to claim 1, wherein one of the first magnetic layer and the second magnetic layer is divided into two portions across an insulation part on the non-magnetic layer

15. The magnetic sensor according to claim 10, wherein a plurality of third electrodes are alternately arranged among the first electrodes with a different distance between neighbored electrodes.

16. The magnetic sensor according to claim 14, wherein an underlayer with lower resistivity than the first and second magnetic layers is arranged under the first and second magnetic layers.
